(19) United States
(12) Patent Application Publication
(10) Pub. No.: US 2026/0106113 A1
(43) Pub. Date: Apr. 16, 2026

(54) CONTROL OF RF POWER DELIVERY AND SPLITTING IN A DISTRIBUTED RF SYSTEM

(71) Applicant: Applied Materials, Inc., Santa Clara, CA (US)

(72) Inventors: David Coumou, Webster, NY (US); Jacob Harrell, Fairport, NY (US); Brian Alvarez, Oceanside, CA (US); Kelvin Chan, San Ramon, CA (US)

(21) Appl. No.: 18/917,917

(22) Filed: Oct. 16, 2024

(51) Int. Cl. H01J 37/32

(52) U.S. Cl. CPC H01J 37/32183; H01J 37/32926

(57) ABSTRACT

Embodiments described herein relate to an apparatus that includes an RF power supply and an RF power splitter with switched outputs. In an embodiment, an apparatus includes a radio frequency (RF) power supply, and an RF power splitter electrically coupled to the RF power supply. In an embodiment, the RF power splitter includes a plurality of outputs. In an embodiment, each one of a plurality of RF impedance matches are electrically coupled to a different one of the plurality of outputs of the RF power splitter. In an embodiment, a plurality of switches are along a different one of a plurality of RF cables that couple each of the plurality of outputs of the RF power splitter to a different one of the plurality of RF impedance matches. In an embodiment, the apparatus further includes a controller communicatively coupled to the plurality of switches and the plurality of RF impedance matches, and the controller is configured to tune the plurality of RF impedance matches to a matched input.

### BACKGROUND

### 1) Field

Embodiments of the present disclosure pertain to the field of distributed radio frequency (RF) power delivery systems with RF power delivery control.

### 2) Description of Related Art

In semiconductor processing facilities (which are sometimes referred to as fabs), plasma chambers are used to process wafers or other substrates. For example, plasma chambers may be used to deposit layers on a wafer, etch layers on a wafer, treat surfaces on the wafer, and/or the like. In some fabs, a plurality of plasma chambers may receive power from a single power source. For example, in the case of a radio frequency (RF) plasma system, a single RF power source may generate power that is distributed to a plurality of plasma chambers. An RF splitter may receive the output from the RF power source and split the incoming RF power into a plurality of outputs. In order to provide uniform processing outcomes in each of the plurality of chambers, the RF power is ideally split evenly between the plurality of outputs by the RF splitter.

However, there are many different variables that can result in uneven power distribution from the single RF power source to the plurality of plasma chambers. For example, different wear on the each of the chambers, differences along each RF power branch, etc. may result in non-uniform power delivery. In some cases, non-uniform power delivery may result in excess reflected power that is propagated back to the RF power source. The reflected power may damage and/or otherwise negatively impact the RF power source. Additionally, power saturated plasmas processes can be insensitive to forward power.

### SUMMARY

Embodiments described herein relate to an apparatus that includes a radio frequency (RF) power supply, and an RF power splitter electrically coupled to the RF power supply. In an embodiment, the RF power splitter includes a plurality of outputs. In an embodiment, each one of a plurality of RF impedance matches are electrically coupled to a different one of the plurality of outputs of the RF power splitter. In an embodiment, a plurality of switches are along a different one of a plurality of RF cables that couple each of the plurality of outputs of the RF power splitter to a different one of the plurality of RF impedance matches. In an embodiment, the apparatus further includes a controller communicatively coupled to the plurality of switches and the plurality of RF impedance matches, and the controller is configured to tune the plurality of RF impedance matches to a matched input. In one embodiment, the tuning and allows deposition to be leveled reactor-to-reactor with the switching operation.

Embodiments described herein relate to a method that includes providing power from a radio frequency (RF) power supply to an RF power splitter electrically coupled to the RF power supply, the RF power splitter comprising a plurality of outputs coupled to corresponding ones of a plurality of RF impedance matches, wherein each of a plurality of switches is along a different one of a plurality of RF cables that couple each of the plurality of outputs of the RF power splitter to a different one of the plurality of RF impedance matches. The method also includes tune the plurality of RF impedance matches to a matched input with a switching operation.

Embodiments described herein relate to a method that includes using a single generator to provide RF power to a plurality of reactors while allowing for time domain adjustment of reactor deposition thickness.

### BRIEF DESCRIPTION OF THE DRAWINGS

FIG. 1A is a schematic illustration of a processing tool with an RF power delivery system with a single RF power source with an output that is distributed to a plurality of plasma chambers, in accordance with an embodiment.

FIG. 1B is a schematic illustration of a processing tool with an RF power delivery system with a single RF power source with an output that is distributed to a plurality of plasma chambers with an RF sensor along each branch between an RF splitter and each plasma chamber, in accordance with an embodiment.

FIG. 2 is a schematic illustration of a processing tool with an RF power delivery system with a single RF power source with an output that is distributed to a plurality of plasma chambers with a switch along each branch between an RF splitter and each plasma chamber, in accordance with an embodiment.

FIG. 3 is a schematic illustration of a splitter for use in a processing tool with an RF power delivery system, in accordance with an embodiment of the present disclosure.

FIG. 4A is a schematic illustration of a reflective switching scheme, in accordance with an embodiment of the present disclosure.

FIG. 4B is a schematic illustration of a non-reflective switching scheme, in accordance with an embodiment of the present disclosure.

FIG. 4C is a schematic illustration of another reflective switching scheme, in accordance with an embodiment of the present disclosure.

FIG. 4D is a schematic illustration of another reflective switching scheme, in accordance with an embodiment of the present disclosure.

FIG. 5A is a schematic illustration of a switching layout, and FIG. 5B is a timing diagram, for the switching scheme of FIG. 4A, in accordance with an embodiment of the present disclosure.

FIG. 6A is a schematic illustration of a switching layout, and FIG. 6B is a timing diagram, for the switching scheme of FIG. 4B, in accordance with an embodiment of the present disclosure.

FIG. 7A is a schematic illustration of a switching layout, and FIG. 7B is a timing diagram, for the switching scheme of FIGS. 4C and 4D, in accordance with an embodiment of the present disclosure.

FIG. 8 illustrates a block diagram of an exemplary computer system of a processing tool, in accordance with an embodiment of the present disclosure.

### DETAILED DESCRIPTION

Distributed radio frequency (RF) power deliver systems with improved RF power delivery control are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

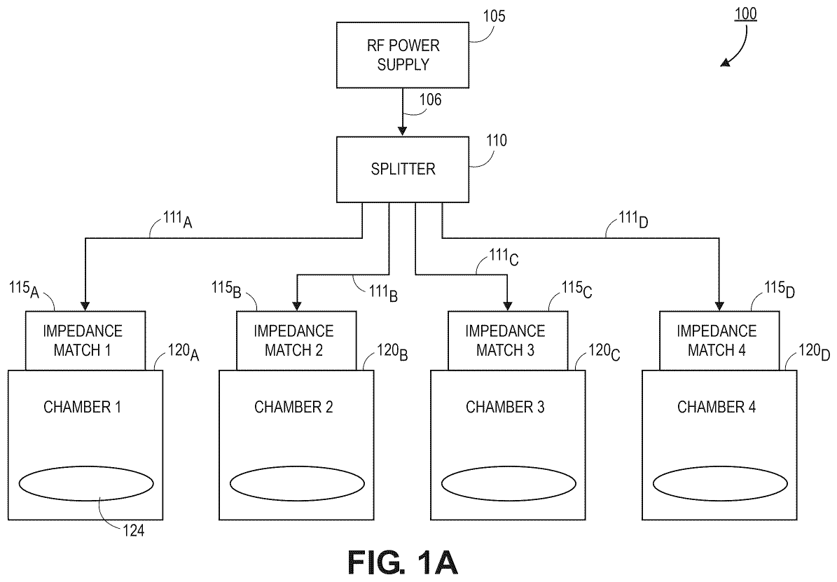

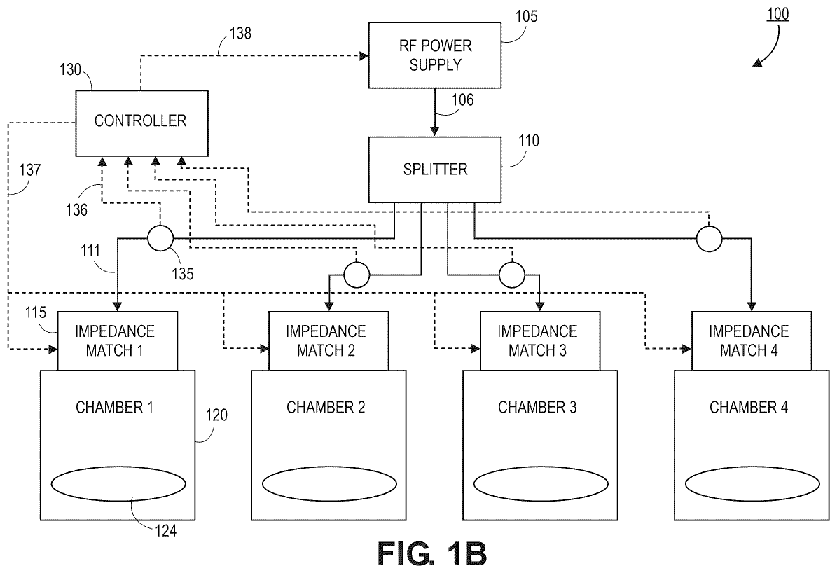

As noted above, distributed radio frequency (RF) power delivery systems rely on precise control of the power delivery along each branch in order to deliver uniform RF power to each of the plasma chambers while minimizing any reflected power that can damage or negatively impact the RF power source. An example of a distributed RF power delivery system 100 is shown in FIG. 1A. FIG. 1A is a schematic illustration of a processing tool with an RF power delivery system with a single RF power source with an output that is distributed to a plurality of plasma chambers, in accordance with an embodiment.

Referring to FIG. 1A, a single RF power supply 105 may be used to supply RF power to a plurality of plasma chambers 120. For example, a set of four plasma chambers 120A-120D is shown in FIG. 1A. In an embodiment, a wafer 124 (or other substrate) that is to be processed (e.g., with an etching process, a deposition process, a plasma treatment process, etc.) may be provided in each of the chambers 120.

In an embodiment, an RF power splitter 110 (which is sometimes simply referred to as a splitter 110) is provided between the RF power supply 105 and the plurality of plasma chambers 120. The splitter 110 may take a single RF power input from the RF power supply 105 (which is delivered along transmission line 106, such as a coaxial cable) and distribute the RF power along a plurality of branches to each of the plasma chambers 120. For example, each branch may include a transmission line 111A-111D, such as a coaxial cable. In an embodiment, each of the plasma chambers 120 may be coupled to a corresponding RF impedance match 115A-115p in order to provide impedance matching along the branch in order to minimize reflected power back towards the splitter 110 and the RF power supply 105. As noted above, minimizing the reflected power allows for improved power delivery efficiency as well as minimizing stress within the RF power delivery system. The matches 115 may include variable capacitors in order to adjust the impedance to account for changing loads within the plasma chambers 120.

In order to mitigate the amount of power balancing required, output power variation introduced by the RF power splitter 110 and RF impedance matching uniformity within the RF power delivery system 100 may be minimized through design choices used in the creation of the RF power delivery system. However, even the best designs may not achieve the necessary power delivery uniformity. As such, the RF power splitting scheme may utilize a power balancing control system in order to account for changes in impedance loading conditions at the output of each RF impedance match 115 and/or variability of RF power at the input of each RF impedance match 115.

Accordingly, embodiments disclosed herein may include a distributed RF power delivery system that includes a centralized controller that samples RF transmission line measurements from a set of RF sensors (e.g., voltage-current (VI) sensors or any other sensor capable of detecting reflected RF power) located along each branch of the distributed RF power delivery system. In an embodiment, data sampled from these sensors is used by the centralized controller to perform one or more impedance tuning operations and/or optimized power balancing to ensure that target setpoint RF power is delivered to each load (i.e., to each plasma chamber).

Whereas traditional power delivery control for distributed RF systems is achieved after the impedance matching networks, embodiments disclosed herein implements the control effort in a consolidated manner to enable greater optimization in the delivery of RF load power to each chamber in the network. This optimization is associated in degree of control and the minimization of RF stress across the RF power system. That is, reflected power back through the system is mitigated in order to protect the RF power source from damage in some embodiments.

In order to implement the power balancing control systems described in greater detail herein, an RF power delivery system 100 with an additional controller and sensors is provided. An example of such an RF power delivery system 100 is shown in FIG. 1B. FIG. 1B is a schematic illustration of a processing tool with an RF power delivery system with a single RF power source with an output that is distributed to a plurality of plasma chambers with an RF sensor along each branch between an RF splitter and each plasma chamber, in accordance with an embodiment.

Referring to FIG. 1B, a plurality of sensors 135 are provided along each branch of the RF power delivery system 100. That is, sensors 135 are provided along transmission lines 111 between the splitter 110 and each of the impedance matches 115. The sensors 135 may be VI sensors in some embodiments. In an embodiment, each of the sensors 135 may be communicatively coupled to a controller 130 by communication paths 136.

The controller 130 may consolidate data from the plurality of sensors 135 in order to implement a power balancing optimization process, such as any of those described in greater detail herein. Generally, the power balancing process may result in the canceling (or minimization) of reflected power along each branch of the RF power delivery system 100. The canceling of reflected power may be the result of a specified “detuning” of one or more of the impedance matches 115. Stated differently, for a given impedance match, the impedance match may be set to a condition where the characteristic impedance is different than the termination impedance. In contrast, the characteristic impedance of a “tuned” impedance match may be substantially equal to the termination impedance.

In an embodiment, the controller 130 may be communicatively coupled to the plurality of impedance matches 115 by communication paths 137. A control effort from the controller 130 may be applied to one or more of the plurality of impedance matches 115 in order to detune the one or more of the plurality of impedance matches by changing a variable capacitance of one or more of the capacitors within the impedance match. In some embodiments, the controller 130 may also be communicatively coupled to the RF power supply 105 by communication path 138 in order to provide control efforts to the RF power supply 105.

As will be described in greater detail herein, the power balancing operations may occur under several different conditions. In a first condition, there is no need for adjusting any of the impedance matches when the load power setpoint is less than or equal to a control threshold. In a second condition, the number of impedance matches to be modified is an even number. In such a condition, antipolar reflection coefficient vectors are generated in order to provide optimal cancelation of reflected power. In a third condition, the number of impedance matches to be modified is an odd number. In such a condition, the maximum detuning to achieve the load power setpoint is used for an even subset of the impedance matches to generate antipolar reflection coefficients, and the remaining impedance match is detuned for the desired load power setpoint. Though, in the third condition a minimal amount of reflected power may be propagated back towards the RF power supply.

In a further aspect, an RF power splitting system with switched outputs for plasma processing applications is described.

In accordance with one or more embodiments of the present disclosure, a method to use a single generator to provide RF power to a plurality of reactors while allowing for time domain adjustment of reactor deposition thickness is described.

To provide context, currently, it is required to use one generator per reactor to allow time tuning, or use power adjustment to tune deposition, some processes are insensitive to power tuning and so require time based tuning wherein the plasma is inactive for some portion of the process. A switching scheme combined with a power splitting scheme can enable the cost savings of a splitter based power delivery scheme while enabling deposition tuning and pulsing based processes.

Advantages for implementing embodiments disclosed herein can include the use of higher wattage generators that are less expensive per watt than low wattage generators. It can be advantageous to drive multiple reactors with a single generator plus a splitter. It is to be appreciated that other approaches require all reactors to remain lit simultaneously, and/or require wafers to be swapped between multiple reactors produce even deposition thickness. One or more embodiments described herein can be implemented to result in single-generator multi-reactor tuned deposition thickness without wafer swapping or tuning gas flow, for power insensitive plasma processes.

To provide further context, it can be advantageous to use a single generator to power multiple plasma reactors. However, many processes tune thickness by time, not by power. This can lead to the need to create a switching scheme that enables time domain control of reactors while limiting reflected power seen by the generator. It can also be desirable to limit stresses on the switching and splitting components to limit cost. It can also be desirable to limit component count.

In accordance with one or more embodiments of the present disclosure, various topologies are considered: (1) a series device, (2) a series device with a matched shunt terminator, and (3) a series device with a set of shunt tuned reactances. In a specific embodiment of case (3), a degenerate case of a series device with a single shunt short device is described. For each such topology, in an embodiment, the switches can be (1) a single module attached to (or integrated into) the splitter, or (2) separate independent modules, or (3) integrated into the matches.

Regarding a controller, in an embodiment, the controller is (1) a separate module that coordinates the other subsystems, or (2) self-contained within each of the matches, with one match acting as a master device, or (3) contained within one of the other subsystems. It is to be appreciated that various modules described and depicted herein need not be separated and are shown as separated for clarity.

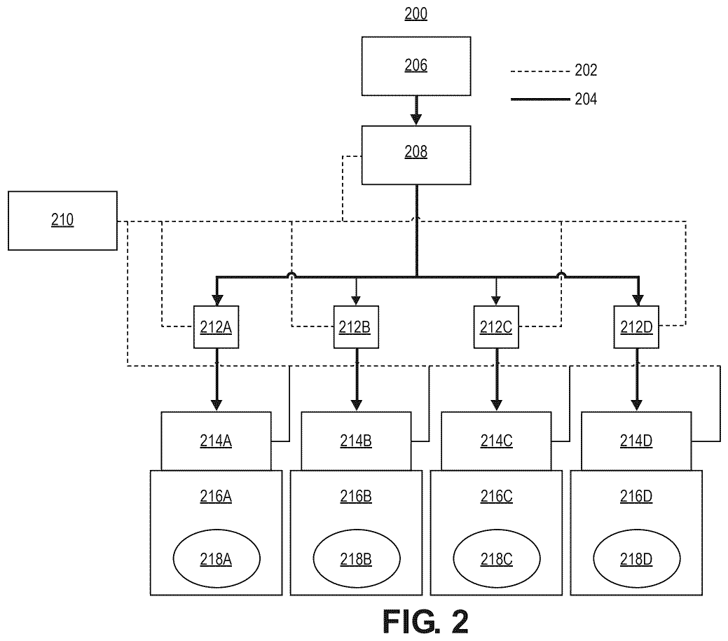

As an exemplary system, FIG. 2 is a schematic illustration of a processing tool with an RF power delivery system with a single RF power source with an output that is distributed to a plurality of plasma chambers with a switch along each branch between an RF splitter and each plasma chamber, in accordance with an embodiment.

Referring to FIG. 2, a system 200 includes control cables 202 and RF cables 204. The RF cables 204 couple an RF power supply 206 to a splitter 208, and couple the splitter 208 to switches 212A, 212B, 212C and 212D, and couple the switches 212A, 212B, 212C and 212D to corresponding impedance matches 214A, 214B, 214C and 214D. The impedance matches 214A, 214B, 214C and 214D are coupled with corresponding process chambers 216A, 216B, 216C and 216D. The process chambers 216A, 216B, 216C and 216D are for processing one or more substrates or wafers 218A, 218B, 218C and 218D therein. The control cables 202 couple a controller 210 to the splitter 208, the switches 212A, 212B, 212C and 212D, and the impedance matches 214A, 214B, 214C and 214D. It is to be appreciated that while four switch/match/chamber pairings are shown, fewer or greater than four such pairings may be included.

In an embodiment, a splitter for use herein is a high isolation splitter, and can be a variant of a Wilkinson splitter. The isolation resistors may be Wye or Delta terminated. In the analysis presented herein, a Wye terminated splitter is considered. The splitter may be recursive (multistage) or single stage. In the analysis presented herein, a single stage is considered. Switching schemes can either limit the power dissipated in S_R1 . . . n, or intentionally dissipate power in S_R1 . . . n to limit the design costs of the switches.

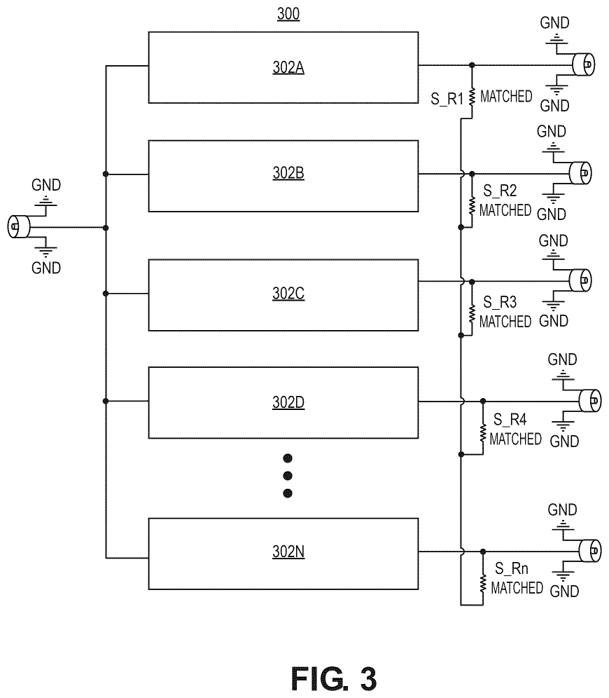

As an exemplary arrangement, FIG. 3 is a schematic illustration of a splitter for use in a processing tool with an RF power delivery system, in accordance with an embodiment of the present disclosure. Referring to FIG. 3, a splitter 300 includes a plurality of impendence transformers 302.

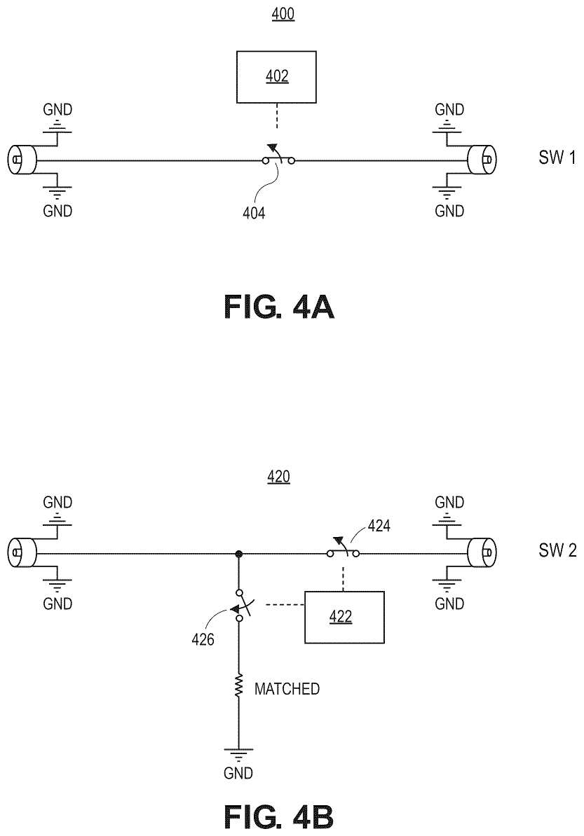

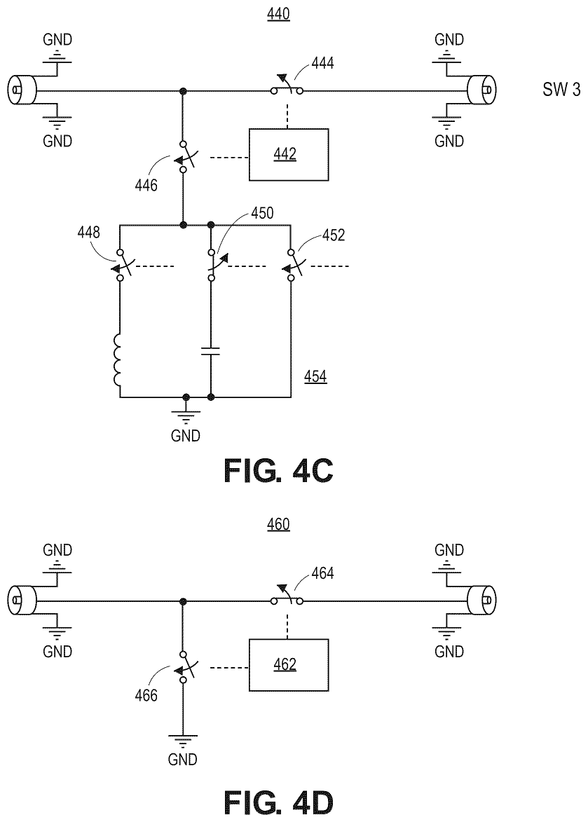

Switching schemes described herein can be reflective in that they dissipate power in the differential terminators and/or reflect power to the generator, or can be non reflective. In a first example, FIG. 4A is a schematic illustration of a reflective switching scheme, in accordance with an embodiment of the present disclosure. Referring to FIG. 4A, a switching scheme 400 includes a control 402 and a switch 404. Switching scheme 400 can be used with an n-arm splitter. Only one reactor should be switched off at a time to limit the standing wave ratio (SWR) seen by the reactor. There can be a finite SWR seen by the generator while each reactor is off.

In a second example, FIG. 4B is a schematic illustration of a non-reflective switching scheme, in accordance with an embodiment of the present disclosure. Referring to FIG. 4A, a switching scheme 420 includes a control 422, a switch 424, and a switch 426. Switching scheme 420 can be used with an n-arm splitter. Any number of reactors may be off simultaneously. There can be a transient finite SWR seen by the generator after any reactor lights or re-lights but not while a reactor is off.

In a third example, FIG. 4C is a schematic illustration of another reflective switching scheme, in accordance with an embodiment of the present disclosure. Referring to FIG. 4C, a switching scheme 440 includes a control 442, a switch 448, a switch 448, a switch 450, a switch 452, and a short 454. Switching scheme 440 can be used with an n-arm splitter. There can be finite SWR seen by the generator after the second-to-last reactor lights before the last reactor lights.

In a fourth example, FIG. 4D is a schematic illustration of another reflective switching scheme, in accordance with an embodiment of the present disclosure. Referring to FIG. 4D, a switching scheme 460 includes a control 462, a switch 464, and a switch 466. Switching scheme 460 can be used with an n-arm splitter, but may be most useful for three or fewer arms. There can be finite SWR seen by the generator after the second-to-last reactor lights before the last reactor lights.

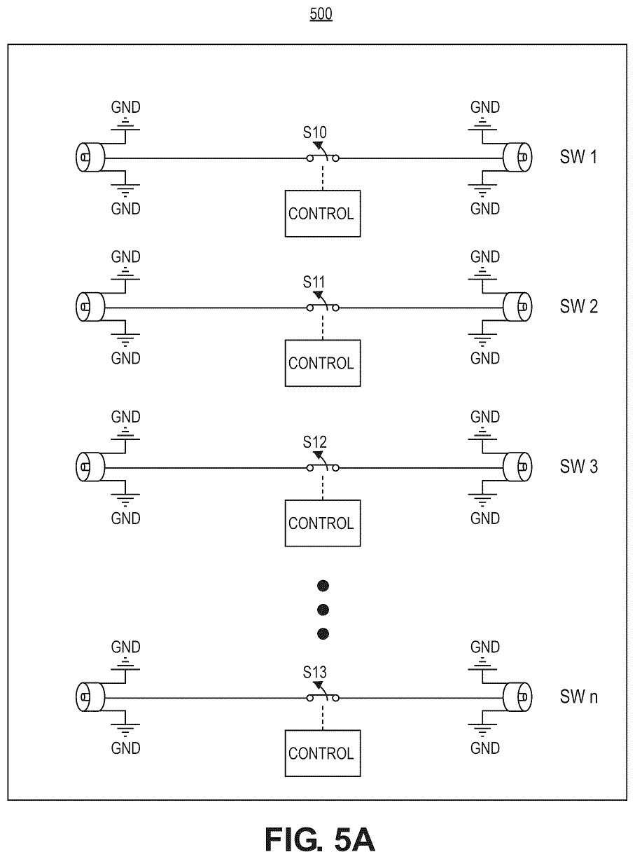

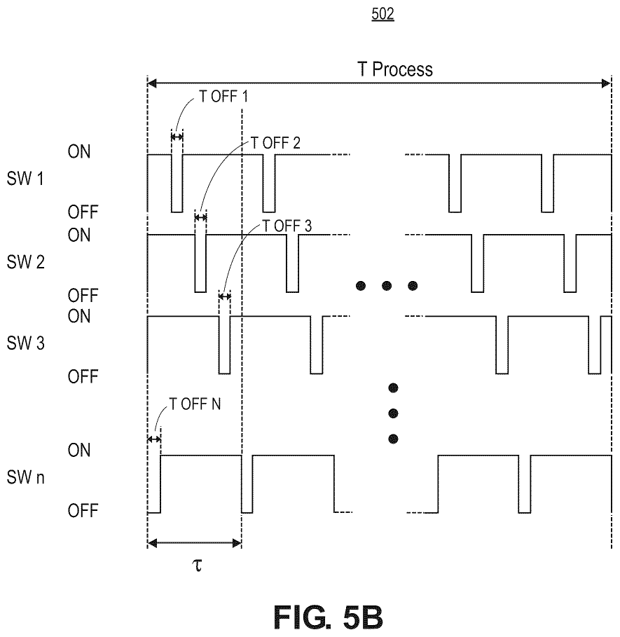

FIG. 5A is a schematic illustration of a switching layout 500, and FIG. 5B is a timing diagram 502, for the switching scheme of FIG. 4A, in accordance with an embodiment of the present disclosure. In the timing diagram 502, only one reactor is off at a time to limit SWR seen by the generator.

Referring to switching layout 500 and to timing diagram 502 of FIGS. 5A and 5B, respectively, during the time each reactor is switched off the generator will see reflected power equal to roughly:

$$\frac{1}{{n}^{2}} * {Pfwd}_{g e n} \qquad Equation 1$$

where n is the number of arms and Pfwd_{gen} is the forward power sourced by the generator. In the wye configuration the splitter differential terminator associated with the off arm will see peak power of approximately:

$$\frac{{Pfwd}_{g e n}}{n} * ( 0.5 + ( ( n - 1 ) * \frac{1}{{n}^{4}} * {Pfwd}_{g e n} ) ) \qquad Equation 2$$

The remaining resistors will see roughly:

$$\frac{1}{{n}^{3}} * {Pfwd}_{g e n} \qquad Equation 3$$

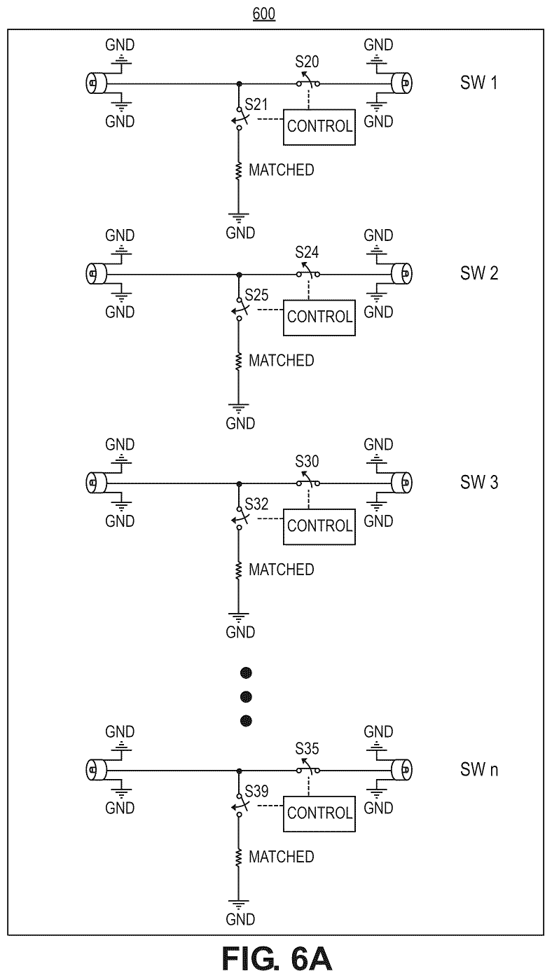

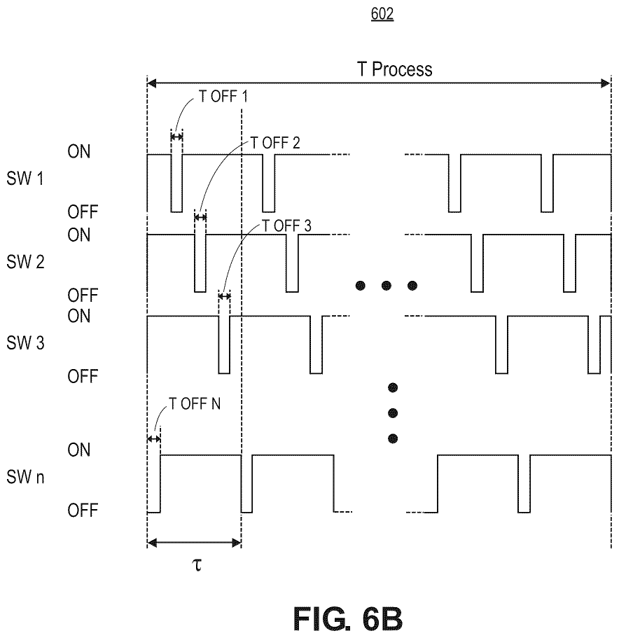

FIG. 6A is a schematic illustration of a switching layout 600, and FIG. 6B is a timing diagram 602, for the switching scheme of FIG. 4B, in accordance with an embodiment of the present disclosure. In the timing diagram 602, the constraint that only one reactor may be off at a time is loosened, as long as only one switches at a time, the SWR seen by the generator can be limited.

During the off time of each reactor the full forward power seen at the input to each switch is dissipated in the matched terminator. At reactor lighting time the transient reflected power seen by the generator will be less than:

$$\frac{1}{{n}^{2}} * Pfwd\_gen for a lighting load with ∞ : 1 SWR \qquad Equation 4$$

where n is the number of arms and Pfwd_gen is the forward power sourced by the generator. In an example, for a 6 kW generator and a 4 way splitter this is 375 Wpk. The peak power dissipated in the worst-case differential resistor will be approximately:

$$Equation 5$$

$$\frac{{Pfwd}_{g e n}}{n} * ( 0.5 + ( ( n - 1 ) * \frac{1}{{n}^{4}} * {Pfwd}_{g e n} ) ) but its duty ratio will b e \frac{{t}_{lighting}}{τ}$$

More realistically the lighting load will have a finite SWR and the reflected power reduce further to:

$$\frac{1}{{n}^{2}} * {Pfwd}_{g e n} * {\vert {Γ}_{{match}_{unlit}} \vert}^{2} \qquad Equation 6$$

Regarding termination resistor power dissipation, the peak power dissipated in a shunt terminator will be equal to:

$$\frac{1}{n} * {P}_{{fwd}_{g e n}} \qquad Equation 7$$

The time-averaged power is limited to:

$$\frac{{t}_{off}}{τ} * \frac{1}{n} * {Pfwd}_{g e n} \qquad Equation 8$$

Where t is the period of the switching and t_{off} is the time the pass-path switch is off, and the shunt switch is conducting. So for a 4 way splitter run at 6000 W with a 94% duty ratio (6% off time) the shunt terminator would see a peak power of 1500 W and an average power of 90 W. t_{off} is limited to some maximum value to respect the peak temperature requirements of the shunt element and t must be limited to some minimum value to ensure plasma performance.

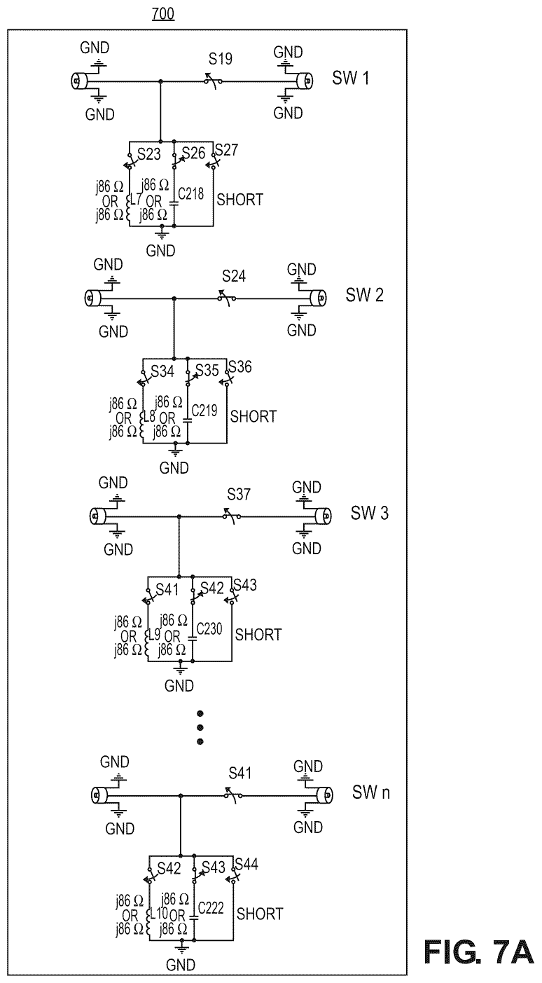

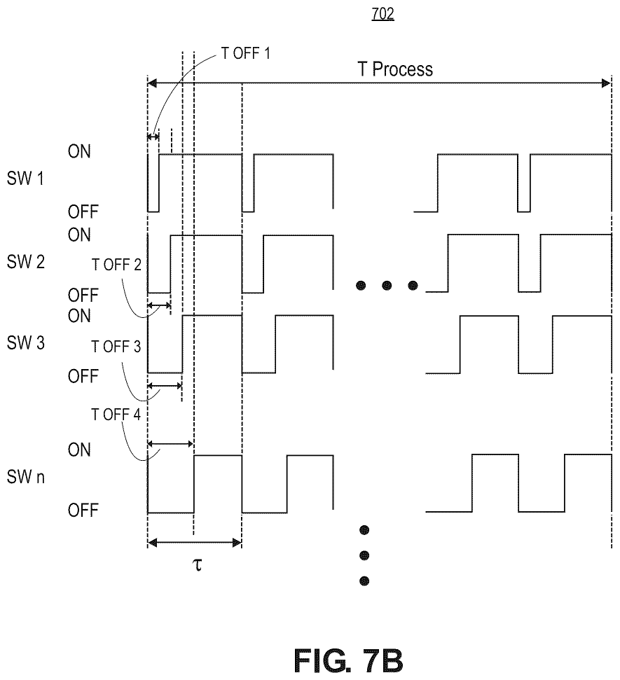

FIG. 7A is a schematic illustration of a switching layout 700, and FIG. 7B is a timing diagram 702, for the switching scheme of FIGS. 4C and 4D, in accordance with an embodiment of the present disclosure.

It is assumed that all reactor on times will be unique. Therefore, there can be a reactor that needs to be on the for the longest time and one that will need to be on for the shortest time and so n+1 switch states are proceeds through. With the exception of the n−1th state (one arm off) each differential terminator for each disabled reactor will dissipate:

$$\frac{{P}_{{fwd}_{g e n}}}{n} \qquad Equation 9$$

for each reactor's off time. In states 0 thru n−2 the SWR seen by the generator can be small. In the n−1th state the dissipation in the splitter and reflected power to the generator will be the same as the scheme of FIGS. 5A and 5B.

As a variation of the scheme of FIGS. 7A and 7B, an alternate scheme has the same behavior but is useful for a 3 way splitter. In an embodiment, the scheme can have the same behavior but only for the case where two chambers remain lit will it produce a matched input impedance. For greater than three reactors, it will step back and forth between finite SWR and a matched condition as an even or odd number of reactors are lit. This can be useful at lower powers or where input SWR matters less or where the switching hardware must be very inexpensive.

When 2 Reactors are unlit, the worst case differential resistors in the splitter are each dissipating:

$$\frac{1}{n} * {P}_{{fwd}_{g e n}} \qquad Equation 10$$

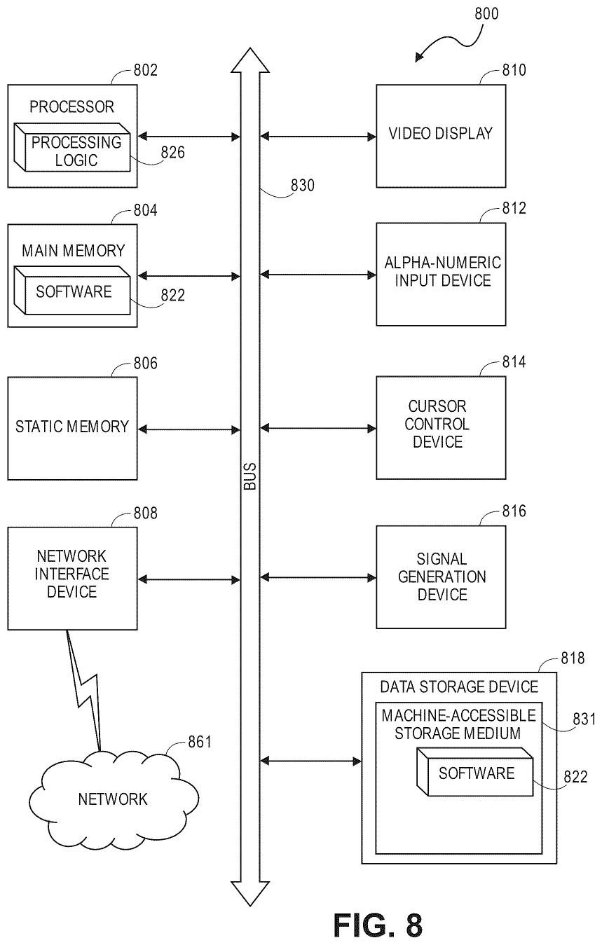

Referring now to FIG. 8, a block diagram of an exemplary computer system 800 of a processing tool is illustrated in accordance with an embodiment. In an embodiment, computer system 800 is coupled to and controls a distributed RF power distribution system and power balancing optimization processes for improved RF power delivery.

Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using microwave coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems that include a distributed RF power distribution system and power balancing optimization processes for improved RF power delivery.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
an RF power splitter configured to electrically couple to an RF power supply, wherein the RF power splitter comprises a plurality of outputs;
a plurality of RF impedance matches, wherein each of the plurality of RF impedance matches is electrically coupled to a different one of the plurality of outputs of the RF power splitter;
a plurality of switches, wherein each of the plurality of switches is along a different one of a plurality of RF cables that couple each of the plurality of outputs of the RF power splitter to a different one of the plurality of RF impedance matches; and
a controller communicatively coupled to the plurality of switches and the plurality of RF impedance matches, wherein the controller is configured to tune the plurality of RF impedance matches to a matched input.

2. The apparatus of claim 1, further comprising:
a plurality of plasma chambers, wherein each of the plurality of RF impedance matches is electrically coupled to a different one of the plurality of plasma chambers.

3. The apparatus of claim 1, wherein the switching operation is a reflective scheme.

4. The apparatus of claim 1, wherein the switching operation is a non-reflective scheme.

5. The apparatus of claim 1, wherein the splitter is a single stage splitter.

6. The apparatus of claim 1, wherein the splitter is a multi-stage splitter.

7. The apparatus of claim 1, wherein the plurality of RF impedance matches comprises four or more RF impedance matches.

8. The apparatus of claim 1, wherein the switching operation comprises switching an odd number of the plurality of RF impedance matches.

9. The apparatus of claim 1, wherein the switching operation comprises switching an even number of the plurality of RF impedance matches.

10. The apparatus of claim 1, wherein the switching operation comprises switching all of the plurality of RF impedance matches.

11. The apparatus of claim 1, wherein the switching operation comprises switching only one of the plurality of RF impedance matches.

12. A method, comprising:
providing power from a radio frequency (RF) power supply to an RF power splitter electrically coupled to the RF power supply, the RF power splitter comprising a plurality of outputs coupled to corresponding ones of a plurality of RF impedance matches, wherein each of a plurality of switches is along a different one of a plurality of RF cables that couple each of the plurality of outputs of the RF power splitter to a different one of the plurality of RF impedance matches; and
tuning the plurality of RF impedance matches to a matched input with a switching operation.

13. The method of claim 12, wherein the switching operation is a reflective scheme.

14. The method of claim 12, wherein the switching operation is a non-reflective scheme.

15. The method of claim 12, wherein the switching operation comprises switching an odd number of the plurality of RF impedance matches.

16. The method of claim 12, wherein the switching operation comprises switching an even number of the plurality of RF impedance matches.

17. The method of claim 12, wherein the switching operation comprises switching all of the plurality of RF impedance matches.

18. The method of claim 12, wherein the switching operation comprises switching only one of the plurality of RF impedance matches.

19. A method, comprising:
using a single generator to provide RF power to a plurality of reactors while allowing for time domain adjustment of reactor deposition thickness.

20. The method of claim 19, wherein the time domain adjustment of reactor deposition thickness is performed without wafer swapping or tuning gas flow for power insensitive plasma processes.
